(19) United States
(12) Patent Application Publication
(10) Pub. No.: US 2001/0032588 A1
(43) Pub. Date: Oct. 25, 2001

(54) Semiconductor film deposition apparatus

(76) Inventors: Kenji Harafuji, Hirakata-shi (JP); Yuzaburo Ban, Hirakata-shi (JP)

Correspondence Address: NIXON PEABODY, LLP, 8180 GREENSBORO DRIVE, SUITE 800, MCLEAN, VA, 22102, US

(21) Appl. No.: 09/838,215

(22) Filed: Apr. 20, 2001

(30) Foreign Application Priority Data
Apr. 21, 2000 (JP) 2000-120763

(51) Int. Cl. C23C 16/00

(52) U.S. Cl. 118/715

(57) ABSTRACT

A semiconductor film deposition apparatus includes: a susceptor for holding a substrate thereon; a reactor body covering the susceptor so that the substrate is exposed inside the reactor body; and a gas inlet portion. The gas inlet portion has an opening with a width smaller than that of the susceptor. Through the gas inlet portion, a source gas is introduced onto the substrate substantially horizontally to the surface of the substrate. And the gas inlet portion is connected airtightly to the reactor body. An inner wall of the gas inlet portion includes a finely roughened region.

### BACKGROUND OF THE INVENTION

The present invention relates to a semiconductor film deposition apparatus for use in depositing a semiconductor film on a wafer by making source gases supplied flow almost horizontally to the surface of the wafer.

Group II-IV or III-V compound semiconductors are direct transition type semiconductors with wide bandgap energy, and are hopefully applicable to emitting light at various wavelengths that range from visible through ultraviolet regions of the spectrum.

Among other things, Group III-V nitride semiconductors, including gallium (Ga) or aluminum (Al) as a Group III constituent and nitrogen (N) as a Group V constituent, have attracted much attention, because those semiconductors exhibit crystallographically excellent properties. Thus, a method for depositing a film of a nitride semiconductor just as intended is in high demand.

A metalorganic chemical vapor deposition (MOCVD) process has been researched and developed widely and vigorously as one of industrially implementable methods of promise.

Hereinafter, a so-called “horizontal MOCVD reactor”, which is so constructed as to make source gases flow horizontally to the wafer surface, will be described as a known semiconductor film deposition apparatus with reference to FIGS. 7A and 7B.

As shown in FIGS. 7A and 7B, the horizontal reactor 200 includes: reactor body 201; gas inlet tube 202 with a gas inlet port 221; and susceptor 211 attached to the bottom of the reactor body 201. In this case, the reactor body 201 and gas inlet tube 202 are made of quartz glass, for example. Also, a gas outlet port 212 is provided at the other end of the reactor body 201 on the opposite side to the gas inlet tube 202.

The susceptor 211 holds a wafer 100 thereon to heat the wafer 100 up to a predetermined temperature.

A source gas 101, introduced through the gas inlet port 221, should be a laminar flow with no vortices after the gas 101 enters the tube 202 through the inlet port 221 and until the gas 101 reaches the space over the susceptor 211. The gas 101 also needs to flow in such a manner as to show spatially uniform velocity distribution over the wafer 100 to grow compound semiconductor crystals of quality.

However, the opening width of the gas inlet port 221 is relatively small as defined by its manufacturing standard, and the gas, introduced through the inlet port 221, should expand to cover an area equal to or greater in width than that of the susceptor 211. For that purpose, the gas inlet tube 202 has an expanded portion 222, the width of which gradually increases from the gas inlet port 221 toward the susceptor 211. In this case, if the angle α of expansion of the expanded portion 222 is large, then a streamline, which has flowed along the inner wall surface of the tube 202, separates from the surface in a velocity boundary layer near the wall of the expanded portion 222 as shown in FIG. 7A. Then, the streamline flows backward, i.e., toward the gas inlet port 221, to turn into a separated streamline (or vortex streamline) 102. Also, a wake, or a vortex 103, is created inside a curvature formed by the separated streamline 102. In other words, a backward flow, moving upstream along the wall surface of the expanded portion 222, is created and then separated from the wall surface at a separation point to form the separated streamline 102. In FIG. 7A, only the streamlines flowing along the wall on the left-hand side of the gas flow are illustrated. Actually, though, similar streamlines also flow along the right-hand-side wall surface almost symmetrically to the illustrated ones about the centerline.

If the vortex 103 is created in the expanded portion 222, then the channel width of the gas flow is substantially decreased or deformed. As a result, the velocity distribution of the gas flow over the susceptor 211 cannot be spatially uniform anymore. In addition, the source gas 101 gets partially stuck inside the vortex 103, thus adversely delaying the exchange of one source gas for another. In that case, even if the semiconductor film being deposited should have its composition changed, the interfacial profile cannot be steep enough.

To solve these problems, G. B. Stringfellow proposed expanding the sidewalls of the expanded portion 222 gently by setting the expansion angle α to 7 degrees or less (see “Organometallic Vapor-Phase Epitaxy”, Second Edition, p. 364, Academic Press).

Another solution is disposing a netlike or porous diffuser 223 in the expanded portion 222 of the gas inlet tube 202 as shown in FIGS. 8A and 8B or 9A and 9B to prevent the vortex from being created in the expanded portion 222.

However, the known horizontal reactor 200 has the following drawbacks. Specifically, if the expansion angle α of the expanded portion 222 is set to about 7 degrees or less, then the distance from the gas inlet port 221 to the gas outlet port 212 of that reactor 200 becomes very long. Accordingly, it may take an excessively large area to dispose such a bulky reactor. Or that long reactor may break very easily, so too much care should be taken in handling such a reactor.

On the other hand, if the diffuser 223 is disposed inside the gas inlet tube 202, then the spatial uniformity in the velocity distribution of the gas flow improves. Nevertheless, the gas flow is reflected by the diffuser 223 to create another type of vortex, thus also delaying the exchange of one source gas for another.

### SUMMARY OF THE INVENTION

It is therefore an object of the present invention to provide a horizontal MOCVD reactor, which is much easier to handle, in which a source gas can flow highly uniformly over the susceptor and in which source gases can be exchanged quickly enough.

To achieve this object, the inner walls of the gas inlet portion are finely roughened in the inventive reactor.

Specifically, an inventive semiconductor film deposition apparatus includes: a susceptor for holding a substrate thereon; a reactor body covering the susceptor so that the substrate is exposed inside the reactor body; and a gas inlet portion. The gas inlet portion has an opening with a width smaller than that of the susceptor. Through the gas inlet portion, a source gas is introduced onto the substrate substantially horizontally to the surface of the substrate. And the gas inlet portion is connected airtightly to the reactor body. An inner wall of the gas inlet portion includes a finely roughened region.

Normally, in a horizontal reactor, the opening width of the gas inlet portion thereof is smaller than the width of a susceptor. Accordingly, the gap between the inner walls of the gas inlet portion naturally expands toward the susceptor. That is to say, the directions in which the walls extend cross the direction in which a source gas flows. In that case, some gas streamlines separate from the walls due to the viscosity the gas has, thereby creating a vortex. However, the inventive semiconductor film deposition apparatus includes a finely roughened region at the inner wall of the gas inlet portion. Accordingly, in the vicinity of those finely roughened walls, a great number of small vortices are created from the gas flowing through the gas inlet portion. When those numerous small vortices are created near the walls, the effects attained from a gas flow with a lower viscosity are attainable. That is to say, the adhesion of the gas flow to the walls decreases so to speak. For that reason, even if the walls form an (expansion) angle of 7 degrees or more with the centerline running straight from the opening of the gas inlet portion toward the susceptor, the separation phenomenon is observable much less frequently. As a result, a highly uniform gas flow can be obtained and the length of the reactor can be shortened. Furthermore, since no diffuser is needed for the channel of the gas inlet portion, the source gases can be exchanged quickly enough.

In one embodiment of the present invention, the width of the gas inlet portion may be increased stepwise from the opening toward the susceptor.

In an alternative embodiment, the width of the gas inlet portion may be increased smoothly from the opening toward the susceptor.

In another embodiment, a centerline, running straight from the opening to the susceptor, may form a relatively small angle with each said wall of the gas inlet portion at a point closer to the opening, but a relatively large angle with the wall at a point closer to the susceptor.

In an alternative embodiment, the centerline, running straight from the opening to the susceptor, may form a relatively large angle with each said wall of the gas inlet portion at a point closer to the opening, but a relatively small angle with the wall at a point closer to the susceptor.

In still another embodiment, the inner wall of the gas inlet portion may include the finely roughened region and a mirror-polished region that are located closer to the opening and the susceptor, respectively. Then, the gas flow over the susceptor can have its uniformity further increased.

More specifically, if the source gas has a relatively high viscosity, a boundary between the finely roughened and mirror-polished regions is preferably located closer to the susceptor as compared to a situation where the source gas has a relatively low viscosity. In that case, the finely roughened region occupies a greater area on the inner wall of the gas inlet portion. Accordingly, even a source gas with a relatively high viscosity can have its substantial viscosity to the wall decreased just as intended.

Also, if the source gas has a relatively high velocity, a boundary between the finely roughened and mirror-polished regions is preferably located closer to the susceptor as compared to a situation where the source gas has a relatively low velocity. In that case, the finely roughened region occupies a greater area on the inner wall of the gas inlet portion. Accordingly, even an easily separable source gas, flowing at a relatively high velocity, can have its substantial viscosity to the wall decreased just as intended.

In yet another embodiment, if the source gas has a relatively high viscosity, a centerline, running straight from the opening to the susceptor, preferably forms a relatively small angle with each said wall of the gas inlet portion as compared to a situation where the source gas has a relatively low viscosity. Then, even a source gas with a relatively high viscosity, which normally separates from the walls easily, hardly separate therefrom.

In yet another embodiment, if the source gas has a relatively high velocity, a centerline, running straight from the opening to the susceptor, preferably forms a relatively small angle with each said wall of the gas inlet portion as compared to a situation where the source gas has a relatively low velocity. Then, even a source gas flowing at a relatively high velocity, which normally separates from the walls easily, hardly separate therefrom.

In yet another embodiment, the reactor body and the gas inlet portion are preferably made of glass, while the finely roughened region is preferably made of frosted glass.

### BRIEF DESCRIPTION OF THE DRAWINGS

FIGS. 1A and 1B are respectively a plan view and a side view illustrating a semiconductor film deposition apparatus according to a first embodiment of the present invention.

FIG. 2 is a plan view illustrating, to a larger scale, part of the inner wall of the gas inlet tube in the apparatus of the first embodiment.

FIGS. 3A and 3B are respectively a plan view and a side view illustrating a semiconductor film deposition apparatus according to a second embodiment of the present invention.

FIGS. 4A and 4B are respectively a plan view and a side view illustrating a semiconductor film deposition apparatus according to a third embodiment of the present invention.

FIGS. 5A and 5B are respectively a plan view and a side view illustrating a semiconductor film deposition apparatus according to a modified example of the third embodiment.

FIGS. 6A through 6C are plan views illustrating various alternatives for the apparatus of the third embodiment.

FIGS. 7A and 7B are respectively a plan view, and a cross-sectional view taken along the line VIIB-VIIB shown in FIG. 7A, illustrating a known MOCVD reactor.

FIGS. 8A and 8B are respectively a plan view, and a cross-sectional view taken along the line VIIIB-VIIIB shown in FIG. 8A, illustrating another known MOCVD reactor.

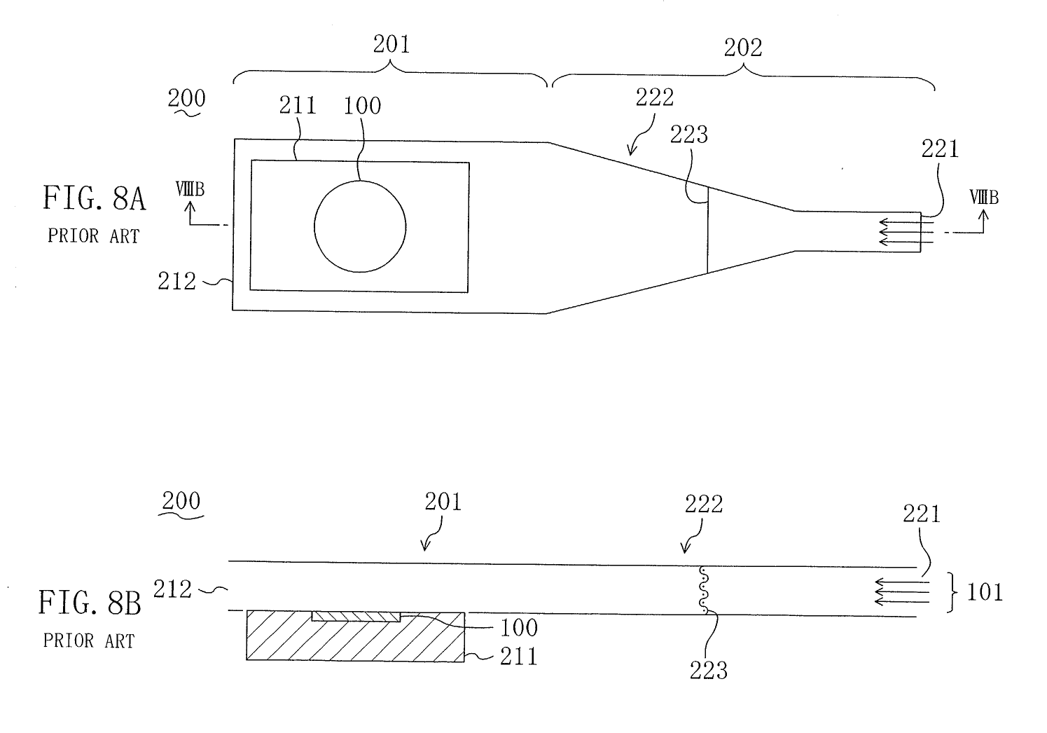

FIGS. 9A and 9B are respectively a plan view and a side view illustrating still another known MOCVD reactor.

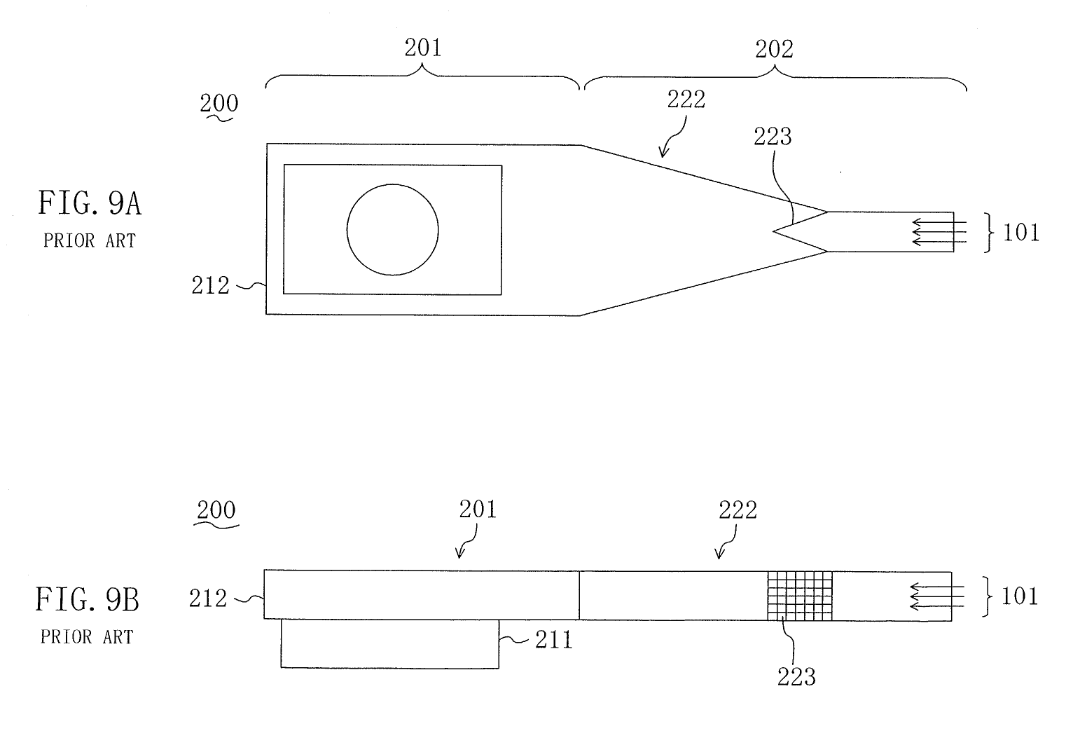

### DESCRIPTION OF THE PREFERRED EMBODIMENTS

EMBODIMENT 1

Hereinafter, a first embodiment of the present invention will be described with reference to the accompanying drawings.

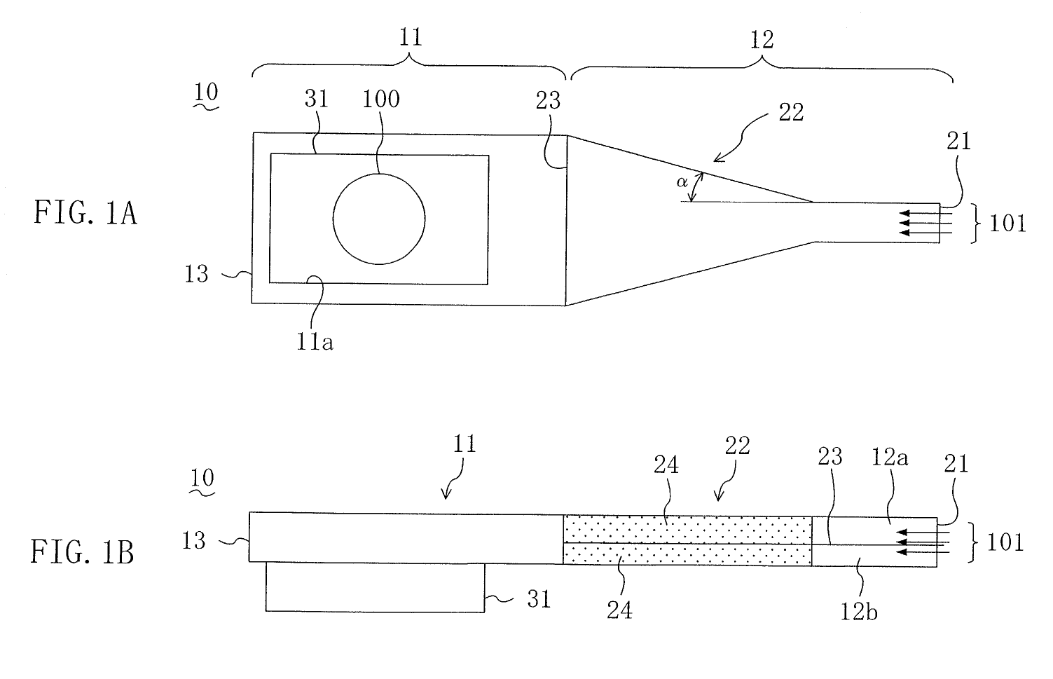

FIGS. 1A and 1B are respectively a plan view and a side view illustrating a semiconductor film deposition apparatus (e.g., horizontal MOCVD reactor) according to the first embodiment.

As shown in FIGS. 1A and 1B, the horizontal reactor 10 includes: reactor body 11; a gas inlet tube 12 with a gas inlet port 21; and susceptor 31 for holding a wafer 100 thereon and heating the wafer 100. The reactor body 11 and gas inlet tube 12 may be made of quartz glass and the susceptor 31 may be made of carbon, for example.

The reactor body 11 includes an opening 11a at the bottom. The susceptor 31, whose bottom is heated by a heater (not shown), for example, is fitted in with the opening 11a so that the wafer 100 is exposed inside the reactor body 11 and that the upper surface of the susceptor 31 is leveled with the bottom of the reactor body 11.

A gas outlet port 13 is provided at the other end of the reactor body 11 on the opposite side to the gas inlet tube 12.

The gas inlet tube 12 has a gas inlet port 21. The opening width of the gas inlet port 21 is smaller than the width of the susceptor 31 as defined by the gas tube manufacturing standard. The gas inlet tube 12 introduces the source gas 101 onto the wafer 100 substantially horizontally to the wafer surface. The other end of the gas inlet tube 12 on the opposite side to the gas inlet port 21 is welded airtightly to the reactor body 11.

Also, the gas inlet tube 12 includes an expanded portion 22, in which the gap between the walls gradually increases from the gas inlet port 21 toward the susceptor 31. In the illustrated embodiment, the expansion angle a formed between each wall of the expanded portion 22 and the centerline running straight from the gas inlet port 21 toward the susceptor 31 is set to about 12 degrees.

The horizontal reactor 10 of the first embodiment is characterized in that a finely roughened region 24 is defined on the inner walls of the expanded portion 22. That is to say, the region 24 has a finely rugged surface like frosted glass.

Furthermore, a partition 23 for dividing the inner space of the gas inlet tube 12 into upper and lower channels 12a and 12b is also disposed inside the gas inlet tube 12.

Hereinafter, it will be described, by way of an illustrative example, how to deposit a semiconductor film of gallium nitride (GaN) crystals on a sapphire wafer 100 using this horizontal reactor 10.

Trimethylgallium (TMG) and hydrogen (H₂) gases are introduced into the upper channel 12a of the gas inlet tube 12 as a Group III source gas and a diluent gas thereof, respectively, at a velocity of about 10 m/sec.

On the other hand, ammonia (NH₃) gas is introduced into the lower channel 12b as a nitrogen source gas at a velocity of about 10 m/sec.

The Group III source gas and the nitrogen source gas are confluent near the junction between the reactor body 11 and the gas inlet tube 12 after having flowed through the upper and lower channels 12a and 12b, respectively. The velocity of the confluent gas over the susceptor 31 is regulated at about 1 m/sec.

Next, it will be described how effective the finely roughened region 24 on the inner walls of the expanded portion 22 is.

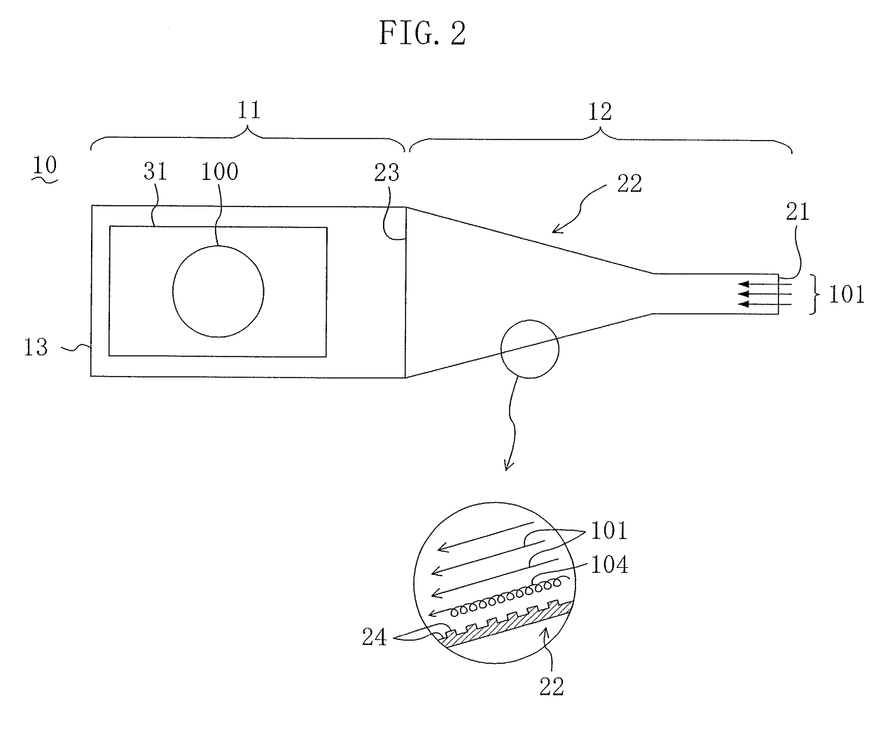

FIG. 2 illustrates, to a larger scale, part of the finely roughened region 24 on the inner wall of the expanded portion 22 of the gas inlet tube 12 in the horizontal reactor 10 of the first embodiment.

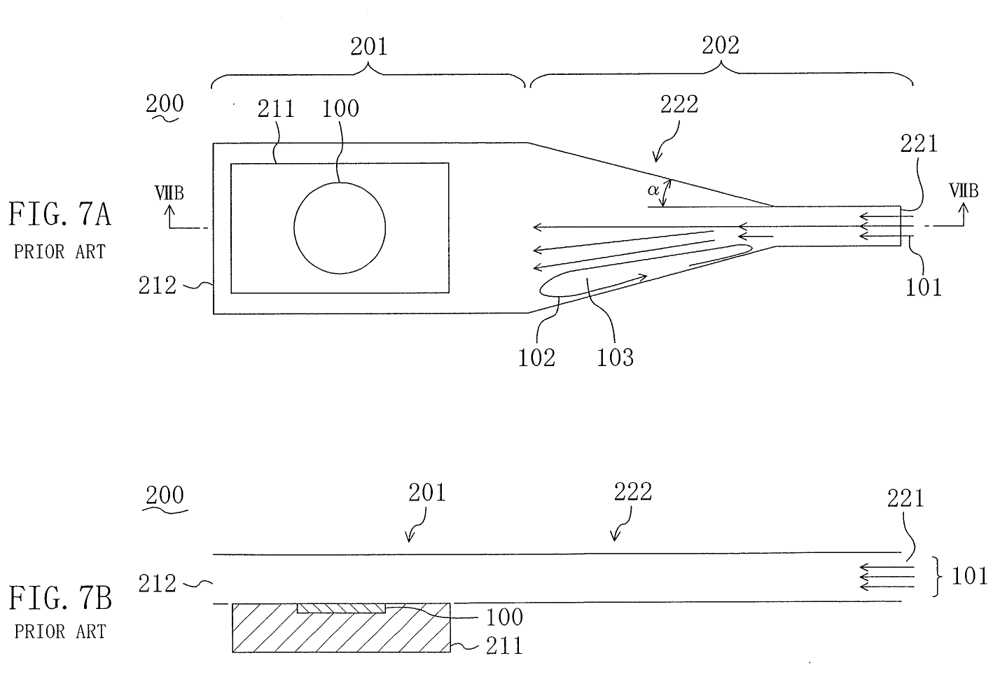

As shown in FIG. 2, a number of small vortices 104 are created near the roughened region 24 on the inner wall of the expanded portion 22. However, no streamlines 102 or large vortices 103 shown in FIG. 7A are created there. Since these small vortices 104 are produced near the inner wall of the expanded portion 22, the effective viscosity of the source gas 101 to the inner wall of the expanded portion 22 decreases. Accordingly, the source gas 101 can be a laminar flow that produces no vertices until the gas 101 reaches the susceptor 31. As a result, the velocity distribution of the gas flow can be substantially uniform spatially over the susceptor 31.

For that reason, even if the expansion angle α is set to as large as about 12 degrees, i.e., greater than 7 degrees, the gas flow much less likely separates from the inner wall of the gas inlet tube 12. Thus, the length of the horizontal reactor 10 can be shortened and yet a uniform gas flow can be obtained. In addition, there is no need to dispose any diffuser inside the gas inlet tube 12, and the source gases 101 can be exchanged quickly enough. Accordingly, where the composition of compound semiconductor crystals being grown should be changed (e.g., GaN should be changed into InGaN by adding indium (In) thereto), the profile at the heterojunction can be changed steeply.

It should be noted that the finely roughened region 24 may be provided not only in the expanded portion 22 but also in another part of the gas inlet tube 12 closer to the gas inlet port 21. That is to say, the roughened region 24 may also be provided in that part where the walls are parallel to each other.

Also, if the gas inlet tube 12 has such a structure that the ceiling thereof gradually increases its height toward the susceptor 31, the ceiling also preferably has the roughened region 24 like frosted glass.

EMBODIMENT 2

Hereinafter, a second embodiment of the present invention will be described with reference to the accompanying drawings.

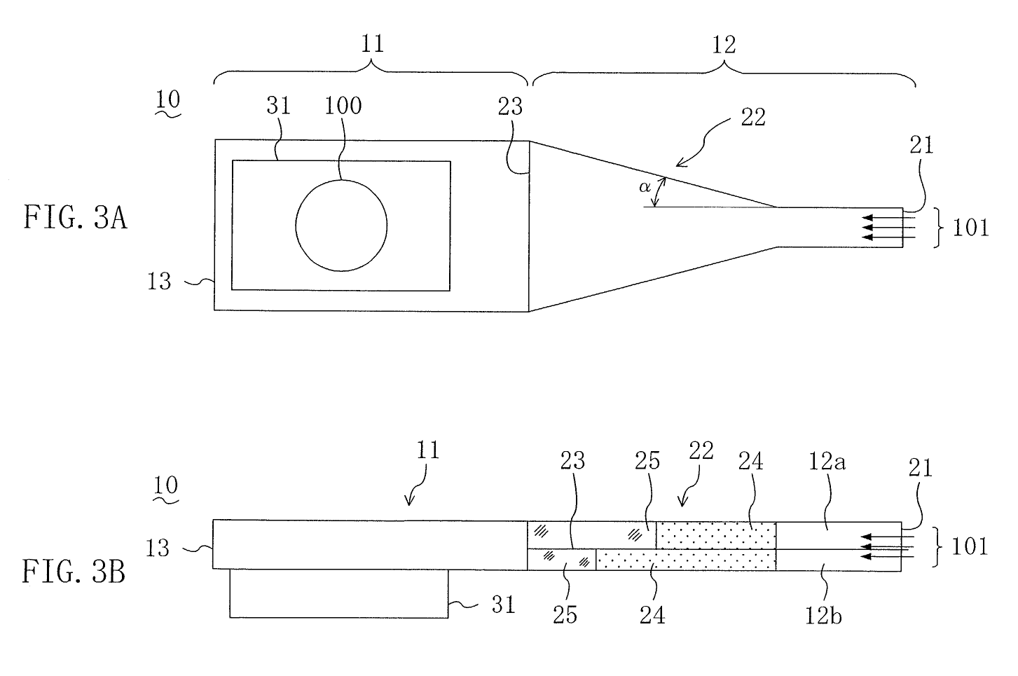

FIGS. 3A and 3B are respectively a plan view and a side view illustrating a semiconductor film deposition apparatus (e.g., horizontal MOCVD reactor) according to the second embodiment. In FIGS. 3A and 3B, each member also shown in FIGS. 1A and 1B is identified by the same reference numeral and the description thereof will be omitted herein.

In the horizontal reactor 10 shown in FIGS. 3A and 3B, the expanded portion 22 of the gas inlet tube 12 has the finely roughened region 24 on part of its inner wall closer to the gas inlet port 21 and a mirror-polished region 25 on the other part of the inner wall.

If the source gas 101 has a relatively high viscosity, the boundary between the finely roughened and mirror-polished regions 24 and 25 is located closer to the susceptor 31 as compared to a situation where the source gas 101 has a relatively low viscosity.

Also, if the source gas 101 has a relatively high velocity, the boundary between the finely roughened and mirror-polished regions 24 and 25 is also located closer to the susceptor 31 as compared to a situation where the source gas 101 has a relatively low velocity.

In the second embodiment, the expansion angle α of the expanded portion 22 is also set to about 12 degrees.

Also, according to the second embodiment, the boundary in the lower channel 12b is located closer to the susceptor 31 than the boundary in the upper channel 12a is as shown in FIG. 3B.

Hereinafter, it will be described, by way of an illustrative example, how to deposit a semiconductor film of gallium nitride (GaN) crystals on a sapphire wafer 100 using this horizontal reactor 10.

In this example, ammonia gas as a nitrogen source gas has a higher viscosity than that of hydrogen gas diluting TMG gas as a Group III source gas. Accordingly, the ammonia gas is introduced into the lower channel 12b.

Specifically, the hydrogen gas that dilutes the TMG gas is introduced at a velocity of about 8 m/sec into the upper channel 12a of the gas inlet tube 12a, while the ammonia gas is introduced at a velocity of about 12 m/sec into the lower channel 12b thereof.

According to the second embodiment, the mirror-polished region 25 is defined on part of the inner wall of the expanded portion 22 closer to the susceptor 31. Thus, the small vertices 104 shown in FIG. 2 gradually disappear in the mirror-polished region 25. As a result, the source gas 101 can have its velocity distribution over the susceptor 31 further uniformized spatially.

In addition, according to the second embodiment, the ratio in area between these two regions 24 and 25 is adjusted depending on the viscosity and velocity of the source gas 101. Specifically, if the viscosity or velocity of the source gas 101 is relatively high, then the ratio of the roughened region 24 to the polished region 25 is increased. Accordingly, it is possible to prevent the source gas flow from separating from the wall surface just as intended.

If the velocity of the source gas 101 should be increased (e.g., where the ammonia gas has a velocity of 15 m/sec), then the boundary between the roughened and polished regions 24 and 25 shown in FIG. 3B is preferably shifted even closer to the susceptor 31. That is to say, the roughened region 24 preferably has an even greater area in that case.

In addition, there is no need to dispose any diffuser inside the gas inlet tube 12, and the source gases 101 can be exchanged quickly enough.

EMBODIMENT 3

Hereinafter, a third embodiment of the present invention will be described with reference to the accompanying drawings.

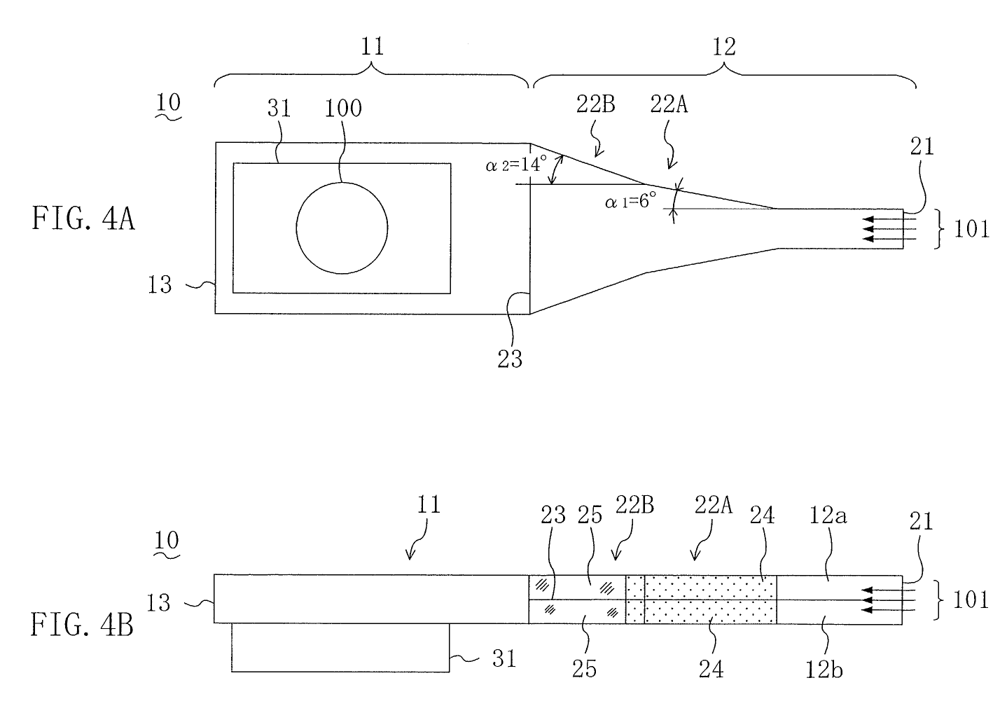

FIGS. 4A and 4B are respectively a plan view and a side view illustrating a semiconductor film deposition apparatus (e.g., horizontal MOCVD reactor) according to the third embodiment. In FIGS. 4A and 4B, each member also shown in FIGS. 1A and 1B is identified by the same reference numeral and the description thereof will be omitted herein.

In the horizontal reactor 10 shown in FIGS. 4A and 4B, the gas inlet tube 12 includes first and second expanded portions 22A and 22B, which are airtightly welded together in this order, i.e., from the gas inlet port 21 toward the susceptor 31. The first and second expanded portions 22A and 22B have mutually different expansion angles. And the second expanded portion 22B is airtightly welded to the reactor body 11.

Specifically, the first expansion angle α₁ of the first expanded portion 22A is set to about 6 degrees and the second expansion angle α₂ of the second expanded portion 22B is set to about 14 degrees. That is to say, part of the gas inlet tube 12 closer to the gas inlet port 21 has the first expansion angle α₁ smaller than the second expansion angle α₂ of the other part thereof closer to the susceptor 31. In this manner, it is possible to prevent the gas flow from separating in the gas inlet tube 12 with more certainty.

In addition, the finely roughened region 24 is defined on the entire side faces of the first expanded portion 22A and parts of the side faces of the second expanded portion 22B closer to the gas inlet port 21. On the other parts of the side faces of the second expanded portion 22B, the mirror-polished region 25 is defined.

According to the third embodiment, the roughened region 24 is defined on the side faces of the first expanded portion 22A and the mirror-polished region 25 is defined on those parts of the side faces of the second expanded portion 22B closer to the susceptor 31. Thus, the small vertices 104 shown in FIG. 2 gradually disappear in the mirror-polished region 25. As a result, the source gas 101 can have its velocity distribution over the susceptor 31 further uniformized spatially.

In addition, there is no need to dispose any diffuser inside the gas inlet tube 12, and the source gases 101 can be exchanged quickly enough.

### MODIFIED EXAMPLE OF EMBODIMENT 3

Hereinafter, a modified example of the third embodiment will be described with reference to the accompanying drawings.

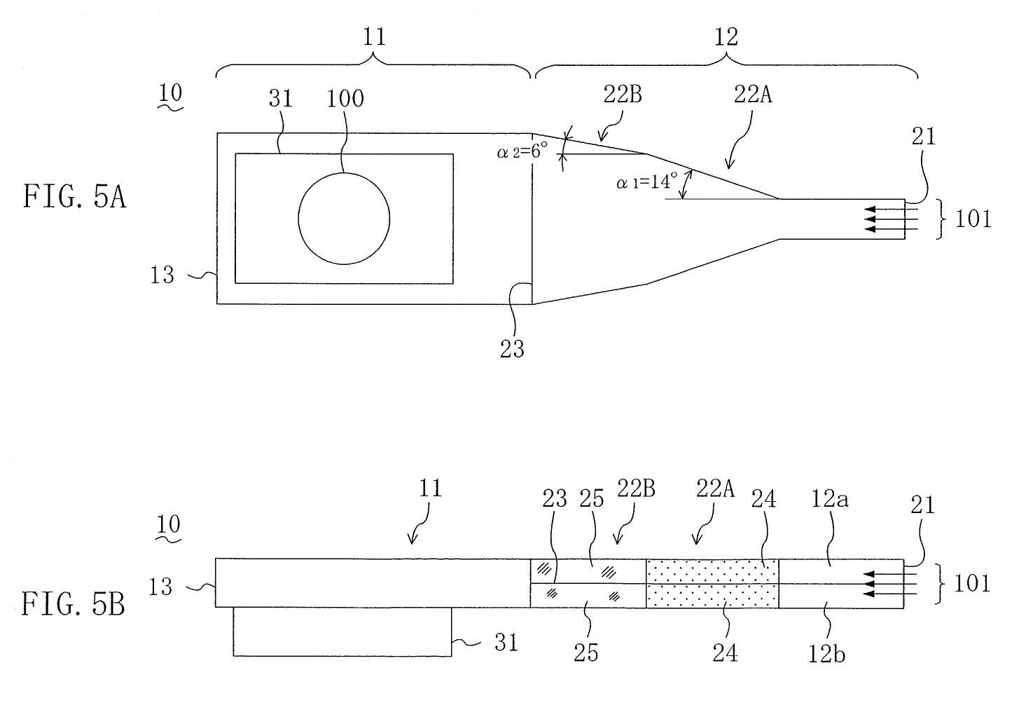

FIGS. 5A and 5B are respectively a plan view and a side view illustrating a semiconductor film deposition apparatus (e.g., horizontal MOCVD reactor) according to a modified example of the third embodiment. In FIGS. 5A and 5B, each member also shown in FIGS. 4A and 4B is identified by the same reference numeral and the description thereof will be omitted herein.

In the horizontal reactor 10 shown in FIGS. 5A and 5B, the gas inlet tube 12 also includes first and second expanded portions 22A and 22B, which are airtightly welded together in this order, i.e., from the gas inlet port 21 toward the susceptor 31. The first and second expanded portions 22A and 22B also have mutually different expansion angles. And the second expanded portion 22B is airtightly welded to the reactor body 11.

In this modified example, the first expansion angle α₁ of the first expanded portion 22A is set to about 14 degrees and the second expansion angle α₂ of the second expanded portion 22B is set to about 6 degrees. That is to say, part of the gas inlet tube 12 closer to the gas inlet port 21 has the first expansion angle α₁ greater than the second expansion angle α₂ of the other part thereof closer to the susceptor 31. In this manner, the length of the horizontal reactor 10 can be reduced.

In this modified example, the roughened region 24 is defined on the side faces of the first expanded portion 22A and the mirror-polished region 25 is defined on the side faces of the second expanded portion 22B. Thus, the small vertices 104 shown in FIG. 2 gradually disappear in the mirror-polished region 25. As a result, the source gas 101 can have its velocity distribution over the susceptor 31 further uniformized spatially.

In the third embodiment and its modified example, the number of expanded portion stages for the gas inlet tube 12 is two. However, the number of stages may be three or more. Furthermore, it is also effective to change the curvature of the gas inlet tube 12 smoothly.

Also, if the viscosity or velocity of the source gas 101 is relatively high, the expansion angles α₁ and α₂ are preferably small to suppress the creation of vortices.

Moreover, as in the second embodiment, the ratio in area between the roughened and polished regions 24 and 25 is preferably changed depending on the viscosity and velocity of the source gas 101.

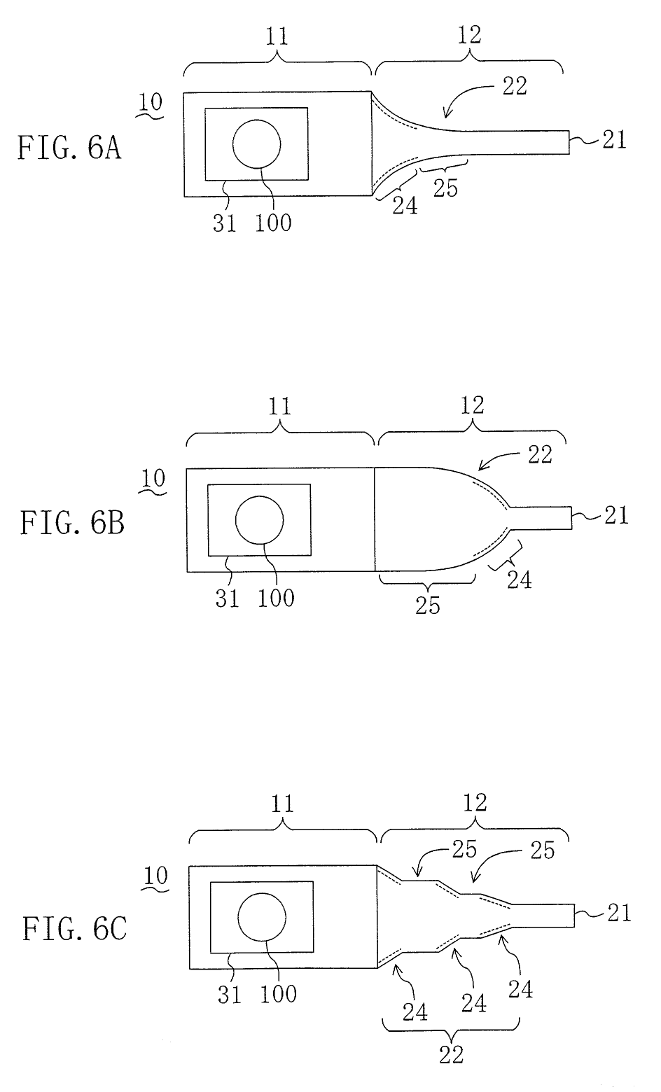

Other modified examples of the third embodiment are illustrated in FIGS. 6A through 6C. As shown in FIGS. 6A and 6B, the expansion angle α of the gas inlet tube 12 may be changed smoothly. Alternatively, the expansion angle α of the gas inlet tube 12 may also be changed stepwise as shown in FIG. 6C. In any of these alternatives, the roughened region 24 may be defined in part of the expanded portion 22 with a relatively large expansion angle, and the mirror-polished region 25 may be defined in the other part thereof with a relatively small expansion angle.

What is claimed is:

1. A semiconductor film deposition apparatus comprising:
a susceptor for holding a substrate thereon;
a reactor body covering the susceptor so that the substrate is exposed inside the reactor body; and
a gas inlet portion, which has an opening with a width smaller than the width of the susceptor, through which a source gas is introduced onto the substrate substantially horizontally to the surface of the substrate and which is connected airtightly to the reactor body,
wherein an inner wall of the gas inlet portion includes a finely roughened region.

2. The apparatus of claim 1, wherein the width of the gas inlet portion is increased stepwise from the opening toward the susceptor.

3. The apparatus of claim 1, wherein the width of the gas inlet portion is increased smoothly from the opening toward the susceptor.

4. The apparatus of claim 1, wherein a centerline, running straight from the opening to the susceptor, forms a relatively small angle with each said wall of the gas inlet portion at a point closer to the opening, but a relatively large angle with the wall at a point closer to the susceptor.

5. The apparatus of claim 1, wherein a centerline, running straight from the opening to the susceptor, forms a relatively large angle with each said wall of the gas inlet portion at a point closer to the opening, but a relatively small angle with the wall at a point closer to the susceptor.

6. The apparatus of claim 1, wherein the inner wall of the gas inlet portion includes the finely roughened region and a mirror-polished region that are located closer to the opening and the susceptor, respectively.

7. The apparatus of claim 6, wherein if the source gas has a relatively high viscosity, a boundary between the finely roughened and mirror-polished regions is located closer to the susceptor as compared to a situation where the source gas has a relatively low viscosity.

8. The apparatus of claim 6, wherein if the source gas has a relatively high velocity, a boundary between the finely roughened and mirror-polished regions is located closer to the susceptor as compared to a situation where the source gas has a relatively low velocity.

9. The apparatus of claim 1, wherein if the source gas has a relatively high viscosity, a centerline, running straight from the opening to the susceptor, forms a relatively small angle with each said wall of the gas inlet portion as compared to a situation where the source gas has a relatively low viscosity.

10. The apparatus of claim 1, wherein if the source gas has a relatively high velocity, a centerline, running straight from the opening to the susceptor, forms a relatively small angle with each said wall of the gas inlet portion as compared to a situation where the source gas has a relatively low velocity.

11. The apparatus of claim 1, wherein the reactor body and the gas inlet portion are made of glass, while the finely roughened region is made of frosted glass.
